(19) United States
(12) Patent Application Publication
(10) Pub. No.: US 2013/0264606 A1
(43) Pub. Date: Oct. 10, 2013

(54) GROUP III NITRIDE SEMICONDUCTOR SUBSTRATE AND METHOD FOR PRODUCING THE SAME, AND SEMICONDUCTOR LIGHT-EMITTING DEVICE AND METHOD FOR PRODUCING THE SAME

(71) Applicant: Mitsubishi Chemical Corporation, Chiyoda-ku (JP)

(72) Inventors: Shuichi KUBO, Ushiku-shi (JP); Hirotaka Ikeda, Ushiku-shi (JP); Hirohisa Itoh, Ushiku-shi (JP); Shinjiro Kadono, Ushiku-shi (JP)

(21) Appl. No.: 13/908,428

(22) Filed: Jun. 3, 2013

Related U.S. Application Data
(63) Continuation of application No. PCT/JP2011/077727, filed on Nov. 30, 2011.

(30) Foreign Application Priority Data
Dec. 1, 2010 (JP) 2010-268598
Dec. 8, 2010 (JP) 2010-273221
Jun. 30, 2011 (JP) 2011-146633

(51) Int. Cl. H01L 31/036; H01L 31/18

(52) U.S. Cl. CPC H01L 31/036; H01L 31/1856
USPC 257/103; 257/615; 438/478; 438/46

(57) ABSTRACT

The problems addressed by the present invention lies in providing a Group III nitride semiconductor substrate having a principal plane on which high-quality crystals can be grown and also providing a method for producing a Group III nitride semiconductor substrate capable of obtaining a crystal which has few stacking faults and in which stacking faults in directions parallel to the polar plane in particular have been greatly suppressed. The problem is solved by means of a Group III nitride semiconductor substrate having a plane other than a C plane as a principal plane, wherein a ratio (W1/W2) of a tilt angle distribution W1 of the principal plane in the direction of a line of intersection between the principal plane and the C plane to a tilt angle distribution W2 of the principal plane in a direction orthogonal to the line of intersection is less than 1.

### CROSS-REFERENCE TO RELATED APPLICATIONS

This is a continuation of International Application PCT/JP2011/077727, filed on Nov. 30, 2011, and designated the U.S., (and claims priority from Japanese Patent Applications 2010-268598 which was filed on Dec. 1, 2010, 2010-273221 which was filed on Dec. 8, 2010, and 2011-146633 which was filed on Jun. 30, 2011) the entire contents of which are incorporated herein by reference.

### TECHNICAL FIELD

The present invention relates to a Group III nitride semiconductor substrate and a method for producing the same, and to a semiconductor light-emitting device and a method for producing the same. More specifically, the invention relates to a Group III nitride semiconductor substrate having a principal plane on which high-quality crystals can be grown, and to a semiconductor light-emitting device provided by using such a substrate to grow a Group III nitride semiconductor.

### BACKGROUND ART

Semiconductor light-emitting devices such as LEDs are generally produced by growing a Group III nitride semiconductor crystal on a substrate. And it is known that when Group III nitride crystals are grown on different kinds of substrates, semiconductor light-emitting devices having a good efficiency cannot be provided on account of the generation of crystal faults, while high-performance semiconductor light-emitting devices can be provided when Group III nitride crystals are homoepitaxially grown on the same kinds of Group III nitride substrates.

Accordingly, a variety of methods for producing Group III nitride substrates have hitherto been developed and proposed in the art. Large-size Group III nitride substrates in which a polar plane serves as the principal plane are relatively easy to produce. However, it has not been easy to produce large-size Group III nitride substrates in which a non-polar plane or a semi-polar plane serves as the principal plane. Various investigations have thus been conducted on methods for producing large-size Group III nitride substrates in which a non-polar plane or a semi-polar plane serves as the principal plane, and a number of production methods have been proposed. For example, a method for producing a Group III nitride substrate by arranging off-substrates having a non-polar plane as the seeds and growing crystals thereon has been proposed (see Patent Document 1). A method for producing a Group III nitride substrate by arranging seeds having various semi-polar planes and growing crystals thereon has also been proposed (see Patent Document 2). Moreover, a method for producing a Group III nitride substrate by arranging seeds having a principal plane such as (20-21) plane and growing crystals thereon has also been proposed (see Patent Document 3).

In addition, Patent Document 4 describes an example where a GaN thin-film in which (10-10) plane serves as the principal plane was grown on (10-10) plane of a sapphire substrate, following which a 1.5 mm thick GaN crystal was grown by a liquid phase process. The same document reports that the number of stacking faults in GaN crystals wherein the (10-10) plane served as the principal plane that were grown was 10⁴ cm^{-1.}
Patent Document 1: Japanese Patent Application Laid-open No. 2010-275171
Patent Document 2: Japanese Patent Application Laid-open No. 2011-16676
Patent Document 3: Japanese Patent Application Laid-open No. 2011-26181
Patent Document 4: Japanese Patent Application Laid-open No. 2010-1209

### DISCLOSURE OF THE INVENTION

However, even when a substrate produced by a conventional method is used and a crystal is grown thereon, because stacking faults or warpage arises, a crystal having a good performance cannot be obtained. Specifically, when LED structures are produced by growing a crystal on a substrate produced by a conventional method, undesirable effects ensue; for example, LED structures having a rough surface are obtained, or LED structures with a low light-emitting efficiency are obtained.

To solve such problems with the conventional art, the inventors have conducted investigations with the aim of, as a first object of the invention, providing a Group III nitride substrate having a principal plane on which high-quality crystals can be grown. In addition, the inventors have conducted investigations aimed at, also as the first object of the invention, providing a semiconductor light-emitting device having a high light-emitting efficiency by growing a Group III nitride crystal on such a substrate.

Although a method which homoepitaxially grows a crystal on a Group III nitride seed in which a polar plane serves as the principal plane, then cuts the crystal so that a desired plane emerges is able to obtain a Group III nitride semiconductor substrate having few stacking faults, a large-size substrate cannot be obtained. On the other hand, when the inventors investigated the method described in Patent Document 4, which involves epitaxially growing a crystal on a Group III nitride seed in which a non-polar plane such as (10-10) plane serves as the principal plane, then cutting from this a substrate in which the (10-10) plane serves as the principal plane, it became apparent for the first time that if an attempt is made to produce a substrate by growing a thick-film crystal, the stacking faults become numerous. That is, in the course of investigations by the inventors, it was found that when thick film growth has been carried out, compared with a Group III nitride crystal obtained by homoepitaxial growth on a Group III nitride seed in which (0001) plane serves as the principal plane, a Group III nitride crystal obtained by homoepitaxial growth on a Group III nitride seed in which (10-10) plane serves as the principal plane has many stacking faults.

In this way, it has not been possible with conventional methods to provide Group III nitride semiconductor substrates which have few stacking faults and are moreover large in size.

Meanwhile, if it is possible to markedly suppress the generation of stacking faults, particularly in directions parallel to the polar plane, when homoepitaxial growth has been carried out on the principal plane of a substrate, it is thought that this would be extremely useful for the production of high-performing and high-efficiency light-emitting devices. However, no methods for providing such Group III nitride semiconductor substrates have hitherto been proposed.

Hence, the inventors, in order to solve such problems in the conventional art, have conducted investigations with the aim of, as a second object of the invention, providing a novel production method capable of obtaining a large-size Group III nitride semiconductor substrate having few stacking faults. In addition, the inventors have conducted investigations aimed at, also as the second object of the invention, providing a Group III nitride semiconductor substrate capable of obtaining, when homoepitaxial growth has been carried out on the principal plane of the substrate, a crystal which has few stacking faults and in which stacking faults in directions parallel to the polar plane in particular have been greatly suppressed.

According to the inventors' analysis of Group III nitride substrates produced in accordance with conventional methods, it was found that there is warpage in each axial direction of two axes being at right angles to each other on the principal plane of the substrate. Although the prior art documents, including Patent Documents 1 to 3, makes no mention of such warpage of the substrate in two axial directions, the inventors, thinking that such warpage might affect the quality of a crystal grown on the substrate, have conducted extensive investigations on the relationship between substrate warpage and the quality of a crystal grown on the substrate. As a result, they have discovered for the first time that, by controlling within a specific range the ratio of the warpage in a specific axial direction and the warpage in a direction orthogonal thereto within the substrate, the quality of a Group III nitride crystal grown on the substrate can be improved. A first aspect of the invention is provided based on such knowledge, and includes the following embodiments.

[1] A Group III nitride semiconductor substrate having a plane other than a C plane as a principal plane, wherein a ratio (W1/W2) of a tilt angle distribution W1 of the principal plane in the direction of a line of intersection between the principal plane and the C plane to a tilt angle distribution W2 of the principal plane in a direction orthogonal to the line of intersection is less than 1.
[2] The Group III nitride semiconductor substrate according to [1], which is a Group III nitride semiconductor substrate having, as the principal plane, an M plane or a plane tilted less than 90° in a c-axis direction from the M plane.
[3] The Group III nitride semiconductor substrate according to [1] or [2], wherein the tilt angle distribution W1 is less than ±1° per 40 mm interval.
[4] The Group III nitride semiconductor substrate according to any one of [1] to [3], wherein the tilt angle distribution W2 is ±0.01° or more and less than ±1° per 40 mm interval.
[5] A method for producing a Group III nitride semiconductor crystal, the method comprising growing a Group III nitride semiconductor crystal on the Group III nitride semiconductor substrate according to any one of [1] to [4].
[6] A method for producing a semiconductor light-emitting device, the method comprising the step of growing a Group III nitride semiconductor crystal on the Group III nitride semiconductor substrate according to any one of [1] to [4].
[7] A semiconductor light-emitting device produced by the method according to [6].
[8] The semiconductor light-emitting device according to [7], wherein the device is an LED.

In addition, as a result of the inventors' extensive investigations in order to achieve the second object, they have discovered that the problems in the conventional art can be solved by carrying out homoepitaxial growth on a semi-polar plane of a seed, then polishing or cutting so that the desired plane emerges.

Hence, in a second aspect, the invention includes the following embodiments.

[9] A method for producing a Group III nitride semiconductor substrate, the method comprising:

(1) a first step of obtaining a Group III nitride semiconductor crystal by carrying out homoepitaxial growth on a semi-polar plane of a Group III nitride seed having the semi-polar plane as a principal plane; and

(2) a second step of acquiring, from the Group III nitride semiconductor crystal, a Group III nitride semiconductor substrate having a plane differing from the semi-polar plane as a principal plane.

[10] The method for producing a Group III nitride semiconductor substrate according to [9], wherein the Group III nitride seed comprises a plurality of Group III nitride seeds, and the Group III nitride seeds are arranged on a same flat surface in such a way that a distribution of plane directions between the principal planes of the seeds is within +0.5°.
[11] The method for producing a Group III nitride semiconductor substrate according to [9] or [10], wherein the Group III nitride seeds are arranged so as to satisfy a condition of the following formula:

Sa/Sc≧1

(In the formula, Sa is a sum of contact distances between edges in the direction of lines of intersection between polar planes and principal planes of the Group III nitride seeds, and Sc is a sum of contact distances between other edges.).
[12] The method for producing a Group III nitride semiconductor substrate according to any one of [9] to [11], wherein the Group III nitride seeds has feature that a total surface area of (0001) planes of the seeds is smaller than a total surface area of (000-1) planes.
[13] The method for producing a Group III nitride semiconductor substrate according to any one of [9] to [12], wherein, in the first step, crystal growth is carried out while controlling an amount of fall in temperature during crystal growth so as to be within 60° C.

By using the Group III nitride semiconductor substrate according to the first aspect of the invention, a high-quality Group III nitride crystal can be grown thereon. Also, by using the production method according to the first aspect of the invention, a high-quality Group III nitride crystal and a semiconductor light-emitting device such as an LED can be produced. The semiconductor light-emitting device of the invention has a high light-emitting efficiency.

In addition, by using the method for producing a Group III nitride semiconductor substrate according to the second aspect of the invention, it is possible to easily provide a large-size Group III nitride semiconductor substrate having few stacking faults. By carrying out homoepitaxial growth on a principal plane of the Group III nitride semiconductor substrate thus produced, it is possible to obtain a crystal which has few stacking faults and in which stacking faults in directions parallel to a polar plane in particular have been markedly suppressed. As a result, by utilizing the Group III nitride semiconductor substrate obtained according to the second aspect of the invention, it is possible to provide semiconductor light-emitting devices having a high light-emitting intensity and an excellent durability.

### BRIEF DESCRIPTION OF THE DRAWINGS

FIG. 1 is a perspective view showing warpage in a Group III nitride semiconductor substrate.

FIG. 2 is a perspective view showing an arrangement of seeds.

FIG. 3 is a schematic view showing an example of production equipment which can be used in the production method of the invention.

FIG. 4 shows fluorescence micrographs of wafers produced in Substrate Production Examples 3, 4 and 5.

FIG. 5 is a graph showing the stacking fault-associated photoluminescence (PL) intensity (low temperature) near 3.41 eV versus the band-edge PL intensity of (10-10) plane sliced substrate in Substrate Production Example 6.

FIG. 6 is a graph showing the stacking fault-associated PL intensity (low temperature) near 3.41 eV versus the band-edge PL intensity of (20-21) plane sliced substrate in Substrate Production Example 6.

### BEST MODE FOR CARRYING OUT THE INVENTION

The Group III nitride semiconductor substrate and the like of the invention are described below in detail. Although the following descriptions of the constituent features of the invention are based on typical embodiments of the invention and specific examples thereof, the invention is not limited to these embodiments and examples.

In the present specification, “principal plane” of a Group III nitride crystal is the largest (broadest) plane in the Group III nitride crystal, and refers to the plane where crystal growth should be carried out. In this specification, “C plane” refers to a plane that is equivalent to {0001} planes in a hexagonal structure (wurtzite-type crystal structure), and is a polar plane. In a Group III nitride crystal, the C plane is a Group III element plane or a Group V element plane; in gallium nitride, these correspond to, respectively, a gallium (Ga) plane or nitrogen (N) plane. Moreover, in the specification, “M plane” refers to non-polar planes collectively represented as {1-100} planes, {01-10} planes, {−1010} planes, {−1100} planes, {0-110} planes and {10-10} planes, and refers specifically to (1-100) plane, (01-10) plane, (−1010) plane, (−1100) plane, (0-110) plane and (10-10) plane. Also, in this specification, “A plane” refers to non-polar planes collectively represented as {2-1-10} planes, {−12-10} planes, {−1-120} planes, {−2110} planes, {1-210} planes and {11-20} planes, and refers specifically to (2-1-10) plane, (−12-10) plane, (−1-120) plane, (−2110) plane, (1-210) plane and (11-20) plane. In this specification, “c axis,” “m axis” and “a axis” refer to axes that are perpendicular to, respectively, a C plane, an M plane and an A plane. Also, in the specification, “off angle” refers to an angle representing the slippage of a given plane from an index plane. “Tilt angle” refers to an angle representing the slippage of a given crystal axis relative to the crystal axis serving as a reference within a crystal plane. In the present specification, this is an angle representing how a crystal axis at another position on the principal plane is displaced from the center crystal axis with reference to the crystal axis at the center of the principal plane of the crystal. In this specification, when a range in numerical values is described as being, for example, “from a to b,” where a is the lower limit value and b is the upper limit value, the range is to be understood as including both the lower limit value and the upper limit value.

The first aspect of the invention is described below. The first aspect of the invention is a Group III nitride semiconductor substrate having a plane other than a C plane as the principal plane. It is a Group III nitride semiconductor substrate characterized in that the ratio (W1/W2) of the tilt angle distribution W1 of the principal plane in the direction of a line of intersection between the principal plane and the C plane to the tilt angle distribution W2 of the principal plane in a direction orthogonal to the line of intersection is less than 1.

(1) Group III Nitride Semiconductor Substrate

(Principal Plane)

The Group III nitride semiconductor substrate of the invention is a Group III nitride semiconductor substrate having a plane other than a C plane as the principal plane. The principal plane of the Group III nitride semiconductor substrate of the invention may be a non-polar plane, a semi-polar plane or a plane tilted from these planes.

In this specification, “non-polar plane” refers to a plane which has both a Group III element and nitrogen present at the surface and in which the abundance ratio therebetween is 1:1. Illustrative examples of preferred non-polar planes include M planes and A planes.

In the specification, “semi-polar plane” refers to, in a case where the Group III nitride is a hexagonal crystal whose principal plane is represented as (hklm), for example, a plane where at least two from among h, i and k is not 0, and l is not 0. Also, a semi-polar plane refers to a plane which is tilted with respect to a C plane such as (0001) plane, and which, in cases where both a Group III element and nitrogen are present at the surface or only one of these is present as in the case of a C plane, has an abundance ratio therebetween which is not 1:1. Also, h, k, l and m are each independently any integer which is preferably from −5 to 5, and more preferably from −2 to 2, and the semi-polar plane is preferably a low-index plane. Examples of semi-polar planes which may be advantageously used as the principal plane of the Group III nitride semiconductor substrate of the invention include (10-11) plane, (10-1-1) plane, (20-21) plane, (20-2-1) plane, (10-12) plane and (10-1-2) plane.

In the specification, when a C plane, an M plane, an A plane or a specific index plane is named, the named plane encompasses planes within a range having an off angle of not more than 10°, preferably not more than 5°, and more preferably not more than 3°, from the respective crystal axes measured to an accuracy of within ±0.01°.

When a specific index plane which is a non-polar plane or a semi-polar plane having an off angle is used as the principal plane of the Group III nitride semiconductor substrate of the invention, the off angle is selected within a range such that the plane after tilting does not become a C plane. The off angle is preferably 0.01° or more, more preferably 0.05° or more, and even more preferably 0.1° or more. The off angle is preferably 10° or less, more preferably 5° or less, and even more preferably 3° or less. It is preferable to select the c-axis direction as the direction of tilt.

In cases where the principal plane of the Group III nitride semiconductor substrate of the invention is a semi-polar plane, this is preferably an M plane or a plane tilted in the c-axis direction from an M plane, or an A plane or a plane tilted in the c-axis direction from an A plane, and is more preferably an M plane or a plane tilted in the c-axis direction from an M plane. In cases where an M plane or a plane tilted in the c-axis direction from an A plane is used as the principal plane, the plane tilted in the c-axis direction from an M plane is exemplified by (20-21) plane and (10-11) plane.

(Tilt Angle Distribution)

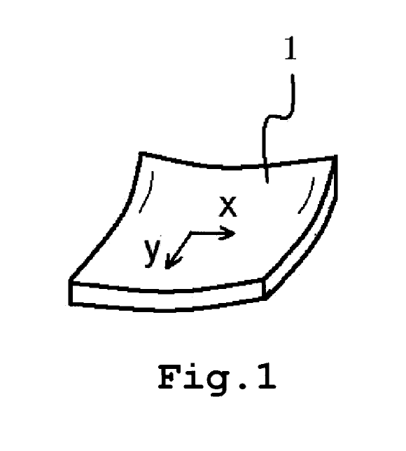

The Group III nitride semiconductor substrate of the invention is characterized in that the ratio (W1/W2) of a tilt angle distribution W1 of the principal plane in the direction of a line of intersection between the principal plane and a C plane to a tilt angle distribution W2 of the principal plane in a direction orthogonal to the line of intersection is less than 1. Referring to FIG. 1, the Group III nitride semiconductor substrate (1) is characterized in that, when the direction of the line of intersection between the principal plane and a C plane is x direction, the ratio of the tilt angle distribution W1 of the principal plane in the x direction to the tilt angle distribution W2 of the principal plane in y direction which is orthogonal to the x direction is less than the above-specified value. For example, in cases where the principal plane is an M plane, the direction of the line of intersection between the principal plane and a C plane becomes a-axis direction, and the ratio (W1/W2) can be determined by dividing the tilt angle distribution of the principal plane in the a-axis direction by the tilt angle distribution of the principal plane in the c-axis direction. Also, in cases where the principal plane is an A plane, the direction of the line of intersection between the principal plane and a C plane becomes the m-axis direction, and the ratio (W1/W2) can be determined by dividing the tilt angle distribution of the principal plane in the m-axis direction by the tilt angle distribution of the principal plane in the c-axis direction.

The tilt angle distribution expresses the degree of warpage. The tilt angle distribution of the principal plane in the invention is determined by measuring the tilt angle at three or more measurement points on each axis. For a detailed account of the measurement method, reference may be made to the subsequently described working examples. The tilt angle distribution is expressed on a 40 mm interval basis.

The tilt angle distribution ratio (W1/W2) in the Group III nitride semiconductor substrate of the invention is preferably less than 1, more preferably less than 0.8, and even more preferably less than 0.5. The lower limit value is preferably 0.01 or more, more preferably 0.02 or more, and even more preferably 0.04 or more.

The tilt angle distribution W1 in the Group III nitride semiconductor substrate of the invention is preferably less than ±1° per 40 mm interval, more preferably less than ±0.5°, and even more preferably less than ±0.2°. The tilt angle distribution W1 is most preferably zero, although when taking a finite value, it is preferably set to, for example, ±0.01° or more.

The above-described tilt angle distribution W1 in the Group III nitride semiconductor substrate of the invention can be restated as the substrate warpage in the direction of the line of intersection between the principal plane and a C plane. The substrate warpage in the direction of the line of intersection is preferably less than 2° per 40 mm, more preferably less than 1°, furthermore preferably less than 0.85°, even more preferably less than 0.65°, still more preferably less than 0.45°, yet more preferably less than 0.4°, and most preferably less than 0.25°.

The tilt angle distribution W2 in the Group III nitride semiconductor substrate of the invention is preferably less than ±1° per 40 mm interval, more preferably less than ±0.8°, and even more preferably less than ±0.5°. The tilt angle distribution W2 may be set to, for example, ±0.01° or more.

The tilt angle distribution W2 in the above-described Group III nitride semiconductor substrate of the invention can be restated as the substrate warpage in a direction orthogonal to the above line of intersection. The substrate warpage in a direction orthogonal to the line of intersection is preferably less than 2° per 40 mm, more preferably less than 1.6°, even more preferably less than 1°, still more preferably less than 0.80°, yet more preferably less than 0.60°, and most preferably less than 0.40°.

The difference between the substrate warpage per 40 mm in the direction of the line of intersection between the principal plane and a C plane and the substrate warpage per 40 mm in a direction orthogonal to the line of intersection is generally from 0.02 to 1.0°, preferably from 0.03 to 0.75°, and more preferably from 0.05 to 0.5°. Warpage of the substrate can be measured by the same method as that used to measure tilt angle distribution in the subsequently described working examples.

The Group III nitride semiconductor substrate of the invention is also characterized in that, unlike conventional Group III nitride semiconductor substrates in which the tilt angle distributions W1 and W2 are both large and the tilt angle distribution ratio (W1/W2) is small, the absolute value of the tilt angle distribution W1 is small and the tilt angle distribution ratio (W1/W2) is small. It has not hitherto been possible to provide such a Group III nitride semiconductor substrate; such a substrate is being provided for the first time in the present invention. Also, this invention demonstrates for the first time that, when use is made of a Group III nitride semiconductor substrate for which the tilt angle distribution ratio (W1/W2) is less than a specific value, a high-quality Group III nitride semiconductor can be grown on the principal plane.

(Group III Nitride Semiconductor)

There is no particular limitation on the kind of Group III nitride semiconductor making up the inventive substrate. Illustrative examples include gallium nitride (GaN), aluminum nitride (AlN), indium nitride (InN), and mixed crystals thereof. Examples of mixed crystals include AlGaN, InGaN, AlInN and AlInGaN. Preferred examples are gallium nitride (GaN) and mixed crystals containing Ga. Gallium nitride (GaN) is more preferred.

The Group III nitride semiconductor substrate of the invention is preferably of a size sufficient to enable a crystal to be grown on the principal plane. For example, the maximum diameter may be set to 10 mm or more, or may even be set to 17 mm or more. The thickness is preferably one that is easy to handle and may be set to, for example 0.2 mm or more, or even 0.3 mm or more. The shape of the substrate is not particularly limited; any of various shapes may be adopted, such as a rectangular, cubic, or cylindrical shape.

(2) Production of Group III Nitride Semiconductor Substrate

(Free-Standing Group III Nitride Substrate)

The method of manufacturing the Group III nitride semiconductor substrate of the invention is not particularly limited, provided the method is capable of producing a substrate which satisfies the conditions of the invention. It is possible for the Group III nitride semiconductor substrate of the invention to be produced by way of, for example, the step of growing a Group III nitride semiconductor on a free-standing Group III nitride substrate of the same kind.

The free-standing Group III nitride substrate may be produced by, for example, slicing from a Group III nitride crystal ingot grown in a specific direction, such that the same principal plane as the principal plane of the Group III nitride semiconductor substrate which is to be produced, or a plane tilted from that principal plane, becomes the principal plane. For example, in cases where the Group III nitride semiconductor is a hexagonal crystal, by slicing from a Group III nitride crystal ingot which has been produced by (0001) plane growth, in such a way that an M plane or a plane tilted somewhat from an M plane becomes the principal plane, it is possible to produce a free-standing Group III nitride substrate. This free-standing Group III nitride substrate may be used for growing a Group III nitride semiconductor substrate having an M plane as the principal plane. In cases where a free-standing Group III nitride crystal is sliced such that a semi-polar plane tilted from an M plane serves as the principal plane, the inclined angle is set to preferably 60° or less, more preferably 45° or less, and even more preferably 30° or less.

When slicing a free-standing Group III nitride substrate from a Group III nitride crystal ingot, slicing in such a way that the total surface area of the (000-1) plane becomes larger than the total surface area of the (0001) plane is preferable for making the W1/W2 ratio of a crystal grown thereon smaller.

It is essential for the size of the free-standing Group III nitride substrate that is sliced to be such as to enable a crystal to be grown thereon. Generally, a shape and size which correspond to the shape of the Group III nitride semiconductor substrate to be produced is selected. For example, the substrate may be rendered into a rectangular, cubic or cylindrical free-standing Group III nitride substrate. In cases where a rectangular free-standing Group III nitride substrate is produced, it is preferable for the length (L1) in the direction of the line of intersection between the principal plane and a C plane to be longer than the length (L2) in a direction within the principal plane that is orthogonal thereto. Specifically, the length ratio (L1/L2) is preferably 1 or more, more preferably 1.5 or more, and even more preferably 2 or more. Also, the length ratio (L1/L2) is preferably 10 or less, more preferably 7 or less, and even more preferably 5 or less. The thickness of the free-standing Group III nitride substrate may be suitably selected while taking into account such considerations as the ease of handling and the ease of crystal growth on the free-standing substrate. This thickness may be set to, for example, preferably 0.2 mm or more, and more preferably 0.3 mm or more, but preferably 5 mm or less, and more preferably 2 mm or less.

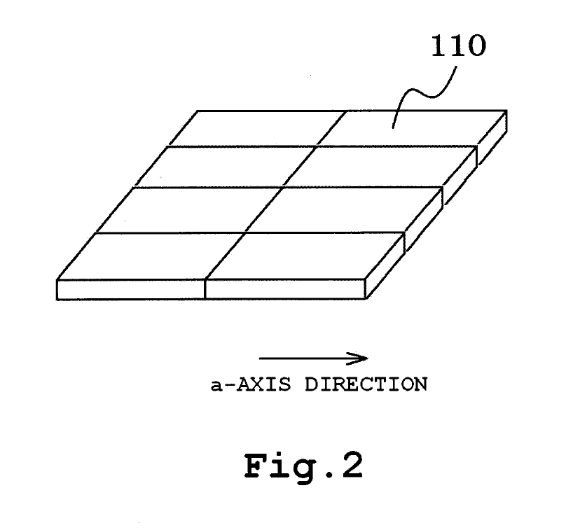

It is also possible to use a free-standing Group III nitride substrate by itself and grow a Group III nitride crystal thereon. However, in terms of the fact that a large Group III nitride crystal can be produced easily, it is preferable to grow a Group III nitride crystal after having arranged in place a plurality of free-standing Group III nitride substrates as seeds. When a plurality of free-standing Group III nitride substrates are arranged, it is preferable to arrange the substrates on the same flat plane with the crystal orientations in alignment and such that at least neighboring free-standing substrates come into mutual contact. Because “crystal orientation” refers here to the inclination of the direction of the normal to the principal plane in each seed, aligning the crystal orientations means to align the off angles among the seeds. It is preferable at this time for the substrates to be arranged in such a way that the edges of the free-standing substrates in the direction of the line of intersection between the principal plane and the C plane are in mutual contact. For example, when arranging free-standing Group III nitride substrates of the same shape as rectangular or cubic bodies containing a principal plane having an edge in the direction of the line of intersection between the principal plane and the C plane and having an edge that is orthogonal thereto, arrangement is carried out such that at least the edges in the direction of the line of intersection between the principal plane and the C plane come into mutual contact, and preferably such that the edges orthogonal thereto also come into mutual contact. Specifically, when rectangular free-standing Group III nitride substrates (seeds 110) having, as the principal plane, an M plane with an edge in the a-axis direction and an edge in the c-axis direction are arranged, as shown in FIG. 2, these substrates can be arranged such that the edges in the a-axis direction come into mutual contact and the edges in the c-axis direction come into mutual contact. At this time, it is preferable that a sum (Sa) of the contact distances between the edges of a-axis direction, which is the direction of the line of intersection between the principal plane and the C plane, is longer than a sum (Sc) of the contact distances between edges of c-axis direction, which is the direction other than the a-axis direction. The ratio (Sa/Sc) between the respective distance sums is preferably 1 or more, more preferably 2 or more, and even more preferably 2.5 or more. The ratio (Sa/Sc) between the respective distance sums is preferably 20 or less, more preferably 15 or less, even more preferably 10 or less, still more preferably 8 or less, and most preferably 5 or less. In cases where the ratio between the respective summated distance is equal to or greater than the bottom limit, it is preferable to have the <0001> (c-axis) direction off-angles in the respective free-standing Group III nitride substrates be in agreement. Also, when a plurality of free-standing Group III nitride substrates are arranged, it is preferable for the directions of the lines of intersections between the principal plane and the C plane for the respective free-standing substrates to be aligned. Moreover, the distribution in the directions of the lines of intersection between the principal plane and the C plane for the respective free-standing substrates is set to preferably within ±5°, more preferably within ±3°, even more preferably within ±1°, and still more preferably within ±0.5°.

Methods that may be used to grow a Group III nitride crystal on a free-standing Group III nitride substrate include hydride vapor-phase epitaxy (HVPE) processes, metal organic chemical vapor deposition (MOCVD) processes, vapor phase processes such as sublimation, liquid phase processes such as liquid phase epitaxy (LPE), and the ammonothermal process. Preferred use can be made of a HVPE process.

(Production Equipment and Production Conditions)

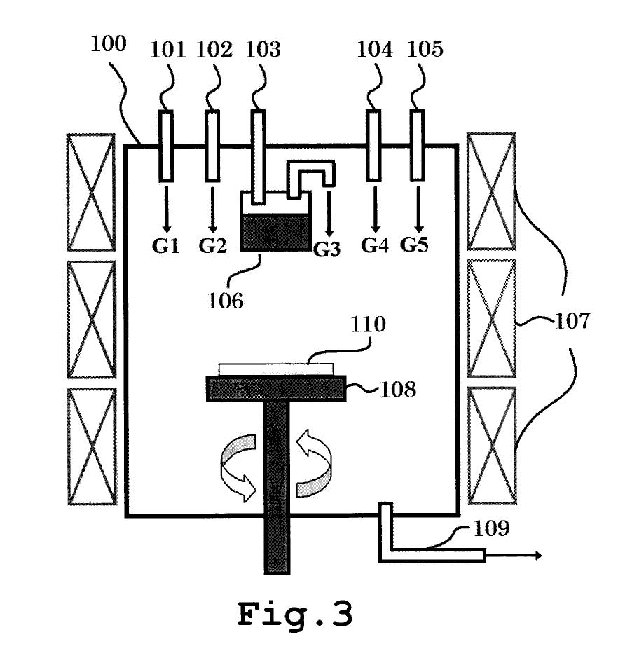

In this invention, a production equipment capable of growing a Group III nitride crystal on a free-standing Group III nitride substrate may be suitably selected and used. The production equipment for an HVPE process is described below, in conjunction with FIG. 3, as an example of a preferred production equipment.

1) Basic Structure

The production equipment in FIG. 3 includes, within a reactor 100: a susceptor 108 for loading a seed 110, and a reservoir 106 which is charged with a starting material for the Group III nitride semiconductor to be grown. Inlets 101 to 105 for introducing gases into the reactor 100 and an exhaust line 109 for discharging exhaust are also provided. In addition, heaters 107 for heating the reactor 100 from side walls thereof are provided.

2) Reactor Material, and Types of Atmospheric Gases

Quartz, sintered boron nitride, stainless steel and the like may be used as the material making up the reactor 100. Quartz is the preferred material. Prior to the start of the reaction, the interior of the reactor 100 is filled with an atmospheric gas. The atmospheric gas (carrier gas) is exemplified by inert gases such as hydrogen, nitrogen, helium, neon and argon. These gases may be used in admixture.

3) Susceptor Material and Shape, and Distance of Susceptor from Growth Face

The material making up the susceptor 108 is preferably carbon, and it is more preferable for the surface to be coated with SiC. The shape of the susceptor 108 is not particularly limited, provided it is a shape that enables the Group III nitride seed used in the invention to be placed thereon. However, it is preferable for there to be no structure present near the crystal growth face during crystal growth. When a structure on which growth may occur is present near the crystal growth face, a polycrystalline body deposits on the structure and HCl gas evolves as a product thereof, which has an adverse influence on the crystal that one is trying to grow. The contact surface between the seed 110 and the susceptor 108 is preferably at least 1 mm removed, more preferably at least 3 mm removed, and even more preferably at least 5 mm removed from the principal plane of the seed (crystal growth face).

4) Reservoir

The starting material for the Group III nitride semiconductor to be grown is charged into the reservoir 106. Specifically, a starting material that serves as a Group III source is charged. Examples of such materials that may become a Group III source include gallium (Ga), aluminum (Al) and indium (In). A gas that reacts with the starting material charged into the reservoir 106 is fed in through an inlet 103 for introducing gas into the reservoir 106. For example, when a starting material serving as the Group III source has been charged into the reservoir 106, HCl gas may be supplied via the inlet 103. At this time, a carrier gas may be supplied via the inlet 103 together with the HCl gas. The carrier gas is exemplified by inert gases such as hydrogen, nitrogen, helium, neon or argon. These gases may be used in admixture.

5) Nitrogen Source (Ammonia), Separation Gas, Dopant Gas

A source gas intended to serve as the nitrogen source is fed in from another inlet 104. NH₃ is generally supplied as the nitrogen source. In addition, a carrier gas is supplied from still another inlet 101. The carrier gas is exemplified by the same gases as the carrier gas supplied via inlet 103. This carrier gas suppresses vapor-phase reactions between the source gases and also has the effect of preventing polycrystal deposition at the nozzle ends. A dopant gas may be fed in through yet another inlet 102. For example, a n-type dopant gas such as SiH₄, SiH₂Cl₂ or H₂S may be supplied.

6) Method of Introducing the Gases

The above gases that are supplied via inlets 101 to 104 may be mutually interchanged and fed in from different inlets that those indicated above. Alternatively the source gas serving as the nitrogen source and the carrier gas may be mixed together and supplied from the same inlet. It is also possible to mix in a carrier gas from yet another inlet. These modes of supply may be suitably selected in accordance with such variables as the size and shape of the reactor 100, the reactivity of the starting materials, and the growth rate of the target crystals.

7) Placement of Exhaust Line

The gas exhaust line 109 may be installed on the top surface, bottom surface or sides of the interior walls of the reactor. To avoid the possibility of falling debris, it is preferable for the gas exhaust line 109 to be positioned below the crystal growth face. Positioning the gas exhaust line 109 on the bottom surface of the reactor, as shown in FIG. 3, is even more preferred.

8) Crystal Growth Conditions

Crystal growth using the above-described production equipment is carried out at preferably 950° C. or above, more preferably 970° C. or above, and even more preferably 980° C. or above. Crystal growth is carried out at preferably 1120° C. or below, more preferably 1100° C. or below, and even more preferably 1090° C. or below. To further lower the W1/W2 ratio, it is preferable to control the temperature during crystal growth so as not to gradually decrease. The amount of fall in temperature during crystal growth is preferably controlled so as to be within 60° C., more preferably controlled so as to be within 40° C., even more preferably controlled so as to be within 20° C., and most preferably controlled so as to be within 10° C. By controlling the amount of fall in temperature during crystal growth within the above range, increases in the tilt angle distribution W1 and the tilt angle distribution W2 that arise due to temperature changes can be prevented, which is desirable. The pressure within the reactor is set to preferably 10 kPa or more, more preferably 30 kPa or more, and even more preferably 50 kPa or more. The pressure is set to preferably 200 kPa or less, more preferably 150 kPa or less, and even more preferably 120 kPa or less.

9) Crystal Growth Rate

The rate of crystal growth using the above-described production equipment varies depending on such factors as the growth process, the growth temperature, the feed rate of the source gases and the direction of the crystal growth face, but is generally in the range of from 5 μm/h to 500 μm/h, preferably 10 μm/h or more, more preferably 50 μm/h or more, and even more preferably 70 μm/h or more. Aside from the above factors, the growth rate can also be controlled by suitably setting, for example, the types and flow rates of the carrier gases, and the distance between the feed port and the crystal growth end.

(Slicing, Shaping, Surface Polishing)

Following crystal growth, to obtain a Group III nitride semiconductor substrate having the desired shape, it is desired that slicing, machining, surface polishing and the like be suitably carried out. Any of these methods may be selected and used alone, or may be used in combination. When used in combination, these methods may be carried out in the following order, for example: slicing, shaping, surface polishing. Describing each of these treatments in detail, “slicing” may be carried out by, for example, cutting the ingot with a wire. “Shaping” refers to rendering the substrate into, for example, a circular or rectangular shape, and may be carried out by a method such as dicing, edge grinding or cutting with a wire. Illustrative examples of surface polishing include methods of polishing the surface using an abrasive such as a diamond abrasive, chemical mechanical polishing (CMP), and damage layer etching by reactive ion etching (RIE) following mechanical polishing.

(3) Production of Group III Nitride Semiconductor Crystal

A Group III nitride semiconductor crystal can be produced by growing a crystal on the principal plane of the Group III nitride semiconductor substrate of the invention. Examples of methods that may be used for growing a Group III nitride crystal on a Group III nitride semiconductor substrate include hydride vapor-phase epitaxy (HVPE) processes, metal organic chemical vapor-phase deposition (MOCVD) processes, liquid-phase processes such as LPE, and the ammonothermal process. Preferred use may be made of a HVPE process. An example of the production equipment for a HVPE process is shown in FIG. 3. The growth conditions for a conventional Group III nitride crystal may be suitably selected and used as the production conditions. The Group III nitride semiconductor crystal grown using the Group III nitride semiconductor substrate of the invention has a high crystal quality and may be advantageously used in semiconductor light-emitting devices and the like.

Because the invention is capable of providing a large-size Group III nitride semiconductor substrate, it is preferable to use a substrate suitable for the size of the Group III nitride semiconductor crystal to be produced. In this invention, it is also possible to arrange together a plurality of Group III nitride semiconductor substrates on a flat surface and have the Group III nitride semiconductor crystal grow thereon so as to bridge the substrates. However, to produce a crystal of significantly higher quality, it is preferable to grow the Group III nitride semiconductor crystal on a single Group III nitride semiconductor substrate.

The second aspect of the invention relates to a method for producing a Group III nitride semiconductor substrate, and includes the following first and second steps.

<Description of First Step>

The first step in the inventive method for producing a Group III nitride semiconductor substrate is the step of obtaining a Group III nitride semiconductor crystal by carrying out homoepitaxial growth on a semi-polar plane of a Group III nitride seed having the semi-polar plane as the principal plane. Here, the principal plane of a Group III nitride seed refers to the largest (broadest) plane in the structure, and is the plane where crystal growth should be carried out.

<Group III Nitride Seed>

The seed used in the first step is composed of a Group III nitride. Examples of Group III nitrides include gallium nitride (GaN), aluminum nitride (AlN), indium nitride (InN), and mixed crystals thereof. In this invention, a seed composed of the same kind of Group III nitride as the Group III nitride semiconductor substrate obtained by the production method of the invention is selected. For example, in cases where a gallium nitride (GaN) semiconductor substrate is produced by the inventive method, a seed composed of gallium nitride (GaN) is used. However, it is not necessary for the seed and the Group III nitride semiconductor substrate to have a completely identical composition; so long as the compositions are at least 99.75% (atomic ratio) in agreement, they may be regarded here as being the same kind of Group III nitride. For example, in a case where a Group III nitride crystal doped with silicon, oxygen or the like is grown on a seed composed of GaN, this is regarded as growing the same kind of Group III nitride and is thus referred to as homoepitaxial growth.

In the Group III nitride seed used in the first step, a semi-polar plane serves as the principal plane.

The principal plane of the Group III nitride seed used in the first step is preferably selected so that the angle with respect to the principal plane of the Group III nitride semiconductor substrate to be produced by the invention method of production is within a specific range. Specifically, it is preferable to select a Group III nitride seed whose principal plane is a plane that intersects the principal plane of the Group III nitride semiconductor substrate produced by the inventive method of production at an angle of from 13 to 49°, more preferable to select a Group III nitride seed whose principal plane is a plane that intersects at an angle of from 13 to 43°, and even more preferable to select a Group III nitride seed whose the principal plane is a plane that intersects at an angle of from 13 to 30°. For example, when producing a Group III nitride semiconductor substrate whose principal plane is (10-10) plane, it is preferable to use a Group III nitride seed whose principal plane is (10-11) plane or (10-1-1) plane that intersects at 28°, or a Group III nitride seed whose principal plane is (20-21) plane or (20-2-1) plane that intersects at 15°. A Group III nitride seed whose principal plane is (20-21) plane or (20-2-1) plane is more preferred. Using these Group III nitride seeds has the desirable effect of reducing stacking faults in the resulting Group III nitride semiconductor crystal.

In the Group III nitride seed, it is preferable for the total surface area of (0001) plane in the seed to be smaller than the total surface area of (000-1) plane. The use of such a seed is desirable because the tilt angle distribution W2 can be made small.

A plurality of Group III nitride seeds may be used in the first step. When a plurality of free-standing Group III nitride substrates are arranged, it is preferable that they be arranged on the same flat surface so that their crystal orientations are in alignment, and so that at least neighboring free-standing substrates are in mutual contact. By thus arranging the substrates so that the crystal orientations are in agreement, the light-emitting efficiency when rendered into a LED structure is improved.

At this time, it is preferable for the free-standing substrates to be arranged in such a way that at least their edges in the direction of the line of intersection between the principal plane and the C plane are in mutual contact. For example, when rectangular or cubic free-standing Group III nitride substrates which are of the same shape and include a principal plane having an edge in the direction of the line of intersection between the principal plane and the C plane and having an edge orthogonal thereto are arranged, arrangement may be carried out such that at least the edges in the direction of the line of intersection between the principal plane and the C plane are in mutual contact, and preferably in such a way that the edges orthogonal thereto also are in mutual contact. Specifically, when rectangular free-standing Group III nitride substrates (seeds 110) whose principal planes are M planes having edges in the a-axis direction and edges in the c-axis direction are arranged, arrangement may be carried out in such a way that, as shown in FIG. 2, the a-axis direction edges are in mutual contact and the c-axis direction edges are in mutual contact. At this time, it is preferable that a sum (Sa) of the contact distances between the edges of a-axis direction, which is the direction of the line of intersection between the principal plane and the C plane, is longer than a sum (Sc) of the contact distances between edges of c-axis direction, which is the direction other than the a-axis direction. The ratio (Sa/Sc) between the respective summated distances is preferably 1 or more, more preferably 2 or more, and even more preferably 2.5 or more. Cases where the distance sum ratio (Sa/Sc) is at least the above lower limit are preferred because the tilt angle distribution W1 can be made smaller. The distance sum ratio (Sa/Sc) is preferably 20 or less, more preferably 15 or less, even more preferably 10 or less, still more preferably 8 or less, and most preferably 5 or less.

The plurality of Group III nitride seeds used may be ones having the same semi-polar plane or may be ones having different semi-polar planes. To achieve uniformity in the resulting Group III nitride semiconductor crystal, the principal planes among the seeds have a distribution of plane directions that is preferably within ±5°, more preferably within ±3°, even more preferably within ±1°, and most preferably within ±0.5°. Because “plane direction” refers to the inclination of the direction of the normal to the principal plane in each seed, a distribution of plane directions being within ±5° means the same thing as an off-angle being within ±5°.

Also, in cases where the distance sum ratio (Sa/Sc) is at least the above lower limit, it is preferable to set the off-angle of <0001> (c-axis) direction within each seed within the above-indicated range.

The method for arranging a plurality of Group III nitride seeds is not particularly limited; the seeds may be arranged next to each other on the same flat surface or they may be arranged next to each other by planar stacking. In cases where the principal planes of the plurality of Group III nitride seeds have differing plane directions, arranging the seeds so that the plane directions of their respective principal planes face in the same direction is preferred because the Group III nitride semiconductor crystal obtained tends to have a good crystallinity over seed junctions.

<Homoepitaxial Growth>

Homoepitaxial growth in the first step entails growing a Group III nitride of the same kind as the Group III nitride making up the seed on a semi-polar plane of the seed. At this time, growth may also be carried out on a plane other than a semi-polar plane that is the principal plane of the Group III nitride seed. Moreover, homoepitaxial growth in the first step, providing it is growth on the principal plane of the Group III nitride seed, need not necessarily involve growth in a direction perpendicular to the principal plane. Also, the direction of growth may change in the course of the first step.

The thickness of the crystal grown on the semi-polar plane of the Group III nitride seed may be suitably selected according to, for example, the size of the Group III nitride semiconductor substrate that one ultimately wishes to obtain. The thickness of the crystal grown on the semi-polar plane of the seed may be set to, for example, from 1 to 51 mm, from 3 to 24 mm, or to from 10 to 14 mm. Here, “thickness” refers to the thickness in the direction perpendicular to the semi-polar plane of the seed.

The specific method of homoepitaxial growth is not particularly limited. For example, preferred use may be made of a hydride vapor-phase epitaxy (HVPE) process, a metal organic chemical vapor deposition (MOCVD) process, a liquid phase process or the ammonothermal process. Preferred use may be made of a HVPE process, a liquid phase process or an ammonothermal process. The production equipment and production conditions which may be used are the same as those described above in connection with the first aspect of the invention.

<Description of Second Step>

The second step in the inventive method for producing a Group III nitride semiconductor substrate is the step of acquiring, from the Group III nitride semiconductor crystal obtained in the first step, a substrate having a plane differing from the semi-polar plane as a principal plane.

<Principal Plane of Substrate>

The principal plane of the Group III nitride semiconductor substrate acquired in the second step is not particularly limited, provided it is a plane that differs from the principal plane of the seed. For example, it may be a non-polar plane or a semi-polar plane.

Illustrative examples of non-polar planes include {10-10} planes and {11-20} planes. Here, “{10-10} planes” refers to so-called M planes, and are planes equivalent to (10-10) plane in a hexagonal structure (wurtzite-type crystal structure); examples include (1-100) plane, (−1100) plane, (01-10) plane, (0-110) plane, (10-10) plane and (−1010) plane. Also, “{11-20} planes” refers to so-called A planes, and are planes equivalent to (11-20) plane in a hexagonal structure (wurtzite-type crystal structure); examples include (11-20) plane, (−1-120) plane, (1-210) plane, (−12-10) plane, (−2110) plane and (2-1-10) plane.

Examples of semi-polar planes include (10-11) plane, (10-1-1) plane, (20-21) plane and (20-2-1) plane.

<Method of Acquiring Substrate>

In the second step, the method of acquiring the target Group III nitride semiconductor substrate from the Group III nitride semiconductor crystal obtained in the first step is exemplified by polishing, cutting, and etching. Any one of these methods may be selected and used, or combinations thereof may be used. When used in combination, it is preferable to carry out polishing after first carrying out cutting or etching. If necessary, it is also possible to carry out etching after polishing. The method which is advantageously used in the second step is polishing, cutting or a combination thereof. When polishing is carried out, after the surface has been polished using an abrasive such as a diamond abrasive, it is possible to set the roughness of the substrate surface within any desired range by a known method such as chemical mechanical polishing (CMP).

In the second step, polishing, cutting, etching and the like are carried out so as to obtain a Group III nitride semiconductor substrate of the desired size. Using the production method of the invention, it is possible to obtain a Group III nitride semiconductor substrate having a relatively large-size principal plane. For example, it is possible to obtain a Group III nitride semiconductor substrate in which the maximum diameter of the principal plane is from 10 to 153 mm, preferably from 18 to 101 mm, and even more preferably from 51 to 77 mm. Here, “maximum diameter” refers to the length of the longest straight line within the principal plane, the shape of the principal plane not being limited to a circular shape.

Also, using the production method of the invention, it is possible to obtain a Group III nitride semiconductor substrate having a thickness of from 0.1 to 2 mm, preferably from 0.2 to 1.5 mm, and more preferably from 0.3 to 0.6 mm.

A Group III nitride semiconductor substrate having very few stacking faults can be obtained by the production method of the invention.

The degree of stacking faults in a Group III nitride semiconductor substrate can be evaluated by fabricating an LED structure on the Group III nitride semiconductor substrate and carrying out photoluminescence (PL) measurement at room temperature. In addition, when an LED structure is fabricated on a Group III nitride semiconductor substrate and examined under a fluorescence microscope, emission lines corresponding to the stacking faults can be confirmed, thus enabling the degree of stacking faults in the Group III nitride semiconductor substrate to be evaluated by means of the intensity of the emission line. Because the stacking faults are plane defects that exist in parallel with the polar plane, in a substrate whose principal plane is a non-polar plane or a semi-polar plane, straight lines corresponding to the sections of stacking faults can be confirmed as the above emission lines. When the production method of the invention is used, it is possible to obtain a Group III nitride semiconductor substrate having an emission line intensity of 200 cm⁻¹ or less, preferably 150 cm⁻¹ or less, and more preferably 100 cm⁻¹ or less.

In addition, it is also possible to assess the degree of stacking faults in a Group III nitride semiconductor substrate by carrying out PL measurement on the substrate itself at a low temperature (10 K). Using the production method of the invention, it is possible to obtain a Group III nitride semiconductor substrate having a stacking fault-associated PL intensity (low temperature) near 3.41 eV which, relative to the band-edge PL intensity, is 0.1 or less, preferably 0.08 or less, and more preferably 0.05 or less.

(4) Semiconductor Light-Emitting Device

The semiconductor light-emitting device of the invention is characterized in that it uses the Group III nitride semiconductor substrate according to the above-described first aspect of the invention, or a Group III nitride semiconductor substrate obtained by the production method according to the second aspect of the invention. Generally, the semiconductor light-emitting device, such as an LED, is produced by using the above-described method to grow a Group III nitride semiconductor crystal on the principal plane of the Group III nitride semiconductor substrate of the invention. Illustrative examples of the Group III nitride semiconductor crystal that is grown include GaN, AlGaN, InGaN, AlInN and AlInGaN. By growing a crystal on the Group III nitride semiconductor substrate according to the first aspect of the invention, it is possible to provide a semiconductor light-emitting device having a higher light-emitting efficiency than in cases where a crystal has been grown on a conventional Group III nitride semiconductor substrate having a principal plane with a large tilt angle distribution (W1/W2).

### EXAMPLES

The features of the invention are illustrated more concretely below by way of working examples of the invention and comparative examples. The materials, usage amounts, ratios, treatment details, order of treatment and the like shown in the following examples can be suitably varied without departing from the gist of the invention. Accordingly, the scope of the invention should not be seen as in any way restricted by the specific examples shown below.

(1) Production of Group III Nitride Semiconductor Substrate

(Substrate Production Example 1)

Eight rectangular free-standing GaN substrates having a principal plane with a 1° off-angle in <0001> (c-axis) direction from (20-21) plane were sliced from a GaN crystal ingot fabricated by (0001) plane growth. The free-standing GaN substrates were each cut to dimensions of 30 mm in <11-20> (a-axis) direction and 17 mm in a direction orthogonal to the a-axis within the principal plane. The distribution of plane directions among the free-standing GaN substrates was within ±0.15°. Using these free-standing GaN substrates as the seeds, the substrates were arranged on a susceptor into two rows in <11-20> (a-axis) direction and four rows in a direction orthogonal to the a-axis in such a way as to align <0001> (c-axis) directions among the free-standing GaN substrates to an accuracy of ±0.25° (see FIG. 2). The sum (Sa) of the contact distances between the edges in the direction of the line of intersection between the principal plane and the C plane was 180 mm, and the sum (Sc) of the contact distances between other edges was 68 mm. Next, as shown in FIG. 3, the susceptor 108 onto which the seeds 110 had been loaded was placed within a reactor 100, the temperature in the reaction chamber was raised to 970° C., and growth of a GaN single-crystal film by the HVPE process was begun. Concurrent with the start of growth, the temperature of the reaction chamber was raised from 970° C. to 1020° C. over one hour, following which growth was effected for 77 hours at a constant temperature of 1020° C. The amount of fall in temperature during growth was less than 5° C. In this single-crystal growth step, the growth pressure from the start of growth to the end of growth was set to 1.01×10⁵ Pa, the partial pressure of the GaCl gas G3 was set to 5.96×10² Pa, and the partial pressure of the NH₃ gas G4 was set to 5.34×10³ Pa. Following completion of the single-crystal growth step, the temperature was lowered to room temperature and a GaN crystal was obtained. The resulting GaN crystal had grown a maximum of 12.0 mm and a minimum of 8.1 mm in <20-21>direction. The grown film thickness distribution showed no particular trend, and was a random film thickness distribution.

The resulting GaN crystal was shaped by dicing, then polished using a diamond abrasive and surface polished by chemical mechanical polishing (CMP), thereby producing 400 μm thick square-shaped free-standing GaN substrates which measured 55 mm on each side and whose principal plane was (10-10) plane (M plane). The tilt angle distributions in <11-20> (a-axis) direction and <0001> (c-axis) direction within the plane of the substrate were measured by running x-ray diffraction ω scans at three points in each direction. Of the three measurement points, one point was located at the center of the substrate and two points were located 20 mm away from the center of the substrate. The measurement results, based on 40 mm intervals, were ±0.11° in <11-20> (a-axis) direction and ±0.35° in <0001> (c-axis) direction. The value obtained by dividing the tilt angle distribution in <11-20> (a-axis) direction by the tilt angle distribution in <0001> (c-axis) direction was 0.31. The tilt angle distributions in the two axial directions were substantially constant within the principal plane.

(Substrate Production Example 2)

Following the same procedure as in Substrate Production Example 1, a GaN crystal was grown on eight rectangular free-standing GaN substrates having a principal plane with a 1° off-angle in <0001> (c-axis) direction from (20-21) plane. The sum (Sa) of the contact distances between the edges in the direction of the line of intersection between the principal plane and the C plane was 180 mm, and the sum (Sc) of the distances between other edges were was 68 mm. The amount of fall in temperature during growth was less than 5° C. The resulting GaN crystal was sliced by cutting with a wire, shaped by dicing, and also polished using diamond abrasive and surface polished by CMP, thereby producing 400 μm thick square-shaped free-standing GaN substrates which measured 55 mm on a side and whose principal plane was (20-21) plane. The tilt angle distributions in <11-20> (a-axis) direction and in a direction orthogonal to the a-axis within the plane of the substrate were measured by running x-ray diffraction ω scans at three points in each direction, as in Substrate Production Method 1. The results, based on 40 mm intervals, were ±0.11° in <11-20> (a-axis) direction and ±0.33° in the direction orthogonal to the a-axis. The value obtained by dividing the tilt angle distribution in <11-20> (a-axis) direction by the tilt angle distribution in the direction orthogonal to the a-axis was 0.33. The tilt angle distributions in the two axial directions were substantially constant within the principal plane.

<Substrate Production Example 3>

A rectangular free-standing GaN substrate whose principal plane was (10-1-1) plane and which had a length of 5 mm in the direction orthogonal to <11-20> (a-axis) within the principal plane and a length of 20 mm in <11-20> (a-axis) direction was prepared, then loaded as the seed 110 onto the susceptor 108. The susceptor 108 with the seed 110 loaded thereon was placed in a reactor 100 as shown in FIG. 3, the temperature of the reaction chamber was raised to 1020° C., and a GaN single-crystal film was grown for 54 hours by the HVPE process. The temperature drop during growth was less than 5° C. In this single-crystal growth step, the growth pressure was set to 1.01×10⁵ Pa, the partial pressure of GaCl gas G3 was set to 5.96×10² Pa, and the partial pressure of NH₃ gas G4 was set to 6.98×10³ Pa. Following completion of the single crystal growth step, the temperature was lowered to room temperature, giving a GaN crystal. The crystal grew a maximum of 4.5 mm in the [10-1-1] direction.

The resulting GaN crystal was shaped and subjected to surface polishing treatment, after which it was sliced by the customary technique, then polishing was subsequently carried out, thereby producing three 330 μm thick free-standing GaN substrates whose principal plane was (10-10) plane. Of the three free-standing GaN substrates obtained, evaluations were carried out on the second substrate from the seed side. The tilt angle distributions in <11-20> (a-axis) direction within the plane of the substrate and in a direction orthogonal to the a-axis within the principal plane were measured by running x-ray diffraction w scans at three points in each direction, as in Substrate Production Method 1. The results, based on 40 mm intervals, were ±0.21° in <11-20> (a-axis) direction and ±0.26° in the direction orthogonal to the a-axis. The value obtained by dividing the tilt angle distribution in <11-20> (a-axis) direction by the tilt angle distribution in the direction orthogonal to the a-axis was 0.81. The tilt angle distributions in the two axial directions were substantially constant within the principal plane.

<Substrate Production Example 4>

Aside from using a free-standing GaN substrate whose principal plane was (20-2-1) plane as the seed, a GaN crystal was obtained under the same conditions as in Substrate Production Example 3. The amount of fall in temperature during growth was less than 5° C. The crystal grew a maximum of 4.8 mm in the [20-2-1] direction. Three free-standing GaN substrates having a thickness of 330 μm were obtained from this crystal by the same method as in Substrate Production Method 3, and the warpage of the second substrate from the seed side was measured. The tilt angle distributions in the <11-20> (a-axis) direction within the plane of the substrate and in a direction orthogonal to the a-axis within the principal plane were measured by running x-ray diffraction ω scans at three points in each direction, as in Substrate Production Method 1. The results, based on 40 mm intervals, were ±0.08° in <11-20> (a-axis) direction and ±0.14° in the direction orthogonal to the a-axis. The value obtained by dividing the tilt angle distribution in <11-20> (a-axis) direction by the tilt angle distribution in the direction orthogonal to the a-axis was 0.57. The tilt angle distributions in the two axial directions were substantially constant within the principal plane.

<Substrate Production Example 5>

Aside from using a free-standing GaN substrate whose principal plane was (10-10) plane as the seed, a GaN crystal was obtained under the same conditions as in Substrate Production Example 3. The amount of fall in temperature during growth was less than 5° C. The crystal grew a maximum of 4.7 mm in the [10-10] direction. Three free-standing GaN substrates having a thickness of 330 μm were obtained from this crystal by the same method as in Substrate Production Method 3, and the warpage of the second substrate from the seed side was measured. The tilt angle distributions in <11-20> (a-axis) direction within the plane of the substrate and in a direction orthogonal to the a-axis within the principal plane were measured by running x-ray diffraction ω scans at three points in each direction, as in Substrate Production Method 1. The results, based on 40 mm intervals, were ±0.15° in <11-20> (a-axis) direction and ±0.60° in the direction orthogonal to the a-axis. The value obtained by dividing the tilt angle distribution in <11-20> (a-axis) direction by the tilt angle distribution in the direction orthogonal to the a-axis was 0.25. The tilt angle distributions in the two axial directions were substantially constant within the principal plane.

<Substrate Production Example 6>

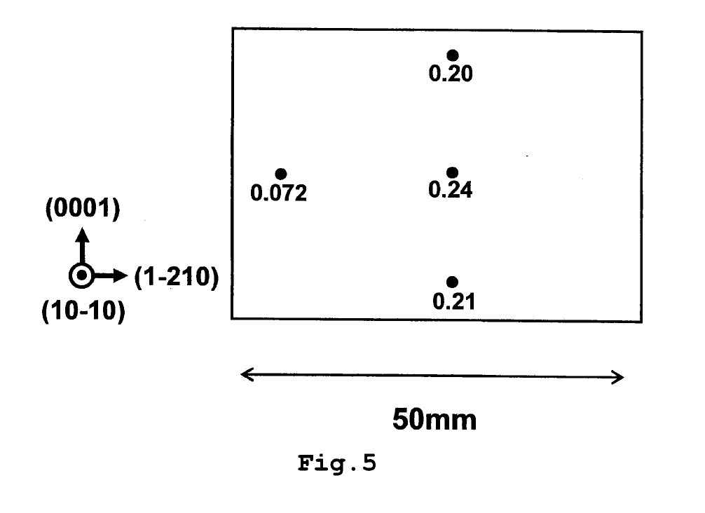

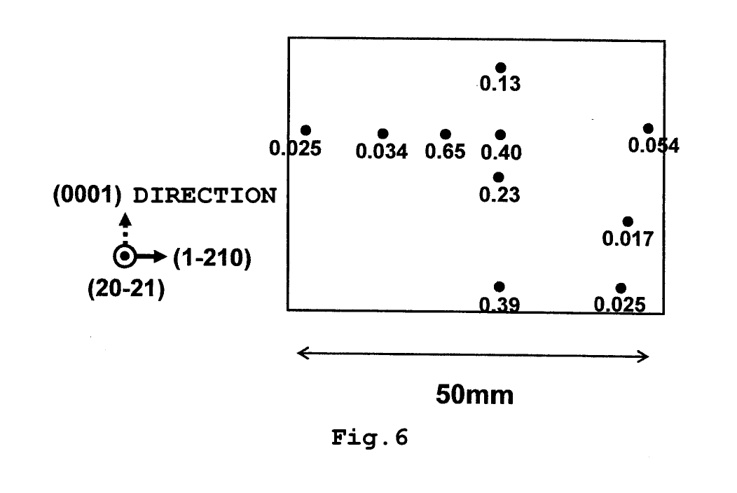

Aside from preparing, as the seeds, eight rectangular free-standing GaN substrates whose principal plane was (20-21) plane and which had a length of 17 mm in the c-axis direction and a length of 25 mm in the a-axis direction, and arranging them into four rows in the c-axis direction and two rows in the a-axis direction in such a way that <0001> (c-axis) directions among the free-standing GaN substrates were aligned to an accuracy of ±0.25°, a GaN crystal was obtained under the same conditions as in Substrate Production Example 3. The sum (Sa) of the contact distances between the edges in the direction of the line of intersection between the principal plane and the C plane was 150 mm, and the sum (Sc) of the contact distances between other edges was 68 mm. The distribution in the plane directions among the free-standing substrates was within ±0.15°. The amount of fall in temperature during growth was less than 5° C. The crystal had a maximum growth in [20-21] direction of 17 mm. Two crystals were produced under the same conditions, one of the crystals being sliced in (10-10) plane to give a plurality of substrates, from among which 39 mm×53 mm substrates were sampled for measurement, and the other crystal being sliced in (20-21) plane to give a plurality of substrates, from among which 38 mm×53 mm substrates were sampled for measurement. PL measurement was carried out at a measurement temperature of 10 K using a He—Cd laser having a center wavelength of 325 nm as the excitation light source. The stacking fault-associated PL intensity (low temperature) near 3.41 eV, relative to the band-edge PL intensity, was investigated, whereupon the results shown in FIG. 5 were obtained for substrates sliced in (10-10) plane, and the results shown in FIG. 6 were obtained for substrates sliced in (20-21) plane. In both types of substrates, the stacking fault-associated PL intensity (low temperature) near 3.41 eV relative to the band-edge PL intensity was high at the line parallel to the c-axis that passes through the substrate center, whereas the stacking fault-associated PL intensity (low temperature) near 3.41 eV relative to the band-edge PL intensity was low at the end of the substrate on the a-axis direction side thereof. The tilt angle distributions in <11-20> (a-axis) direction within the plane of the substrate and in the direction orthogonal to the a-axis within the principal plane were measured by running x-ray diffraction w scans at three points in each direction, as in Substrate Production Example 1, whereupon, based on 40 mm intervals, the tilt angle distribution was ±0.033° in <11-20> (a-axis) direction and was ±0.22° in the direction orthogonal to the a-axis. The value obtained by dividing the tilt angle distribution in <11-20> (a-axis) direction by the tilt angle distribution in the direction orthogonal to the a-axis was 0.15. The tilt angle distributions in the two axial directions were substantially constant within the principal plane.

(Substrate Production Example 7)

Eight free-standing GaN substrates having principal planes with off-angles of from −1° to 1° in <11-20> (a-axis) direction from (20-21) plane were prepared. These free-standing GaN substrates were arranged as seeds on a susceptor in two rows in <11-20> (a-axis) direction and four rows in a direction orthogonal to the a-axis, in such a way as to align <0001> (c-axis) directions among the free-standing GaN substrates to an accuracy of ±0.25°. The substrates were arranged on the susceptor with those substrates having a −1° off-angle being placed on <11-20> side, and those substrates having a 1° off-angle being placed on <−1-120> side. The sum (Sa) of the contact distances between the edges in the direction of the line of intersection between the principal plane and the C plane was 180 mm, and the sum (Sc) of the contact distances between edges other than these was 68 mm. The amount of fall in temperature during growth was less than 5° C. Using the crystal production equipment shown in FIG. 3, a GaN crystal was grown under the same conditions as in Substrate Production Example 1. The GaN crystal thus obtained was sliced by cutting with a wire, shaped by dicing, then polished using a diamond abrasive and surface polished by CMP, thereby producing a 400 μm thick, square-shaped free-standing GaN substrate which measured 55 mm on a side and whose principal plane was (10-10) plane (M plane). The tilt angle distributions in <11-20> (a-axis) direction and <0001> (c-axis) direction within the plane of the substrate were measured by running x-ray diffraction ω scans at three points in each direction, as in Substrate Production Example 1, whereupon, based on 40 mm intervals, the tilt angle distribution was ±0.81° in <11-20> (a-axis) direction and was ±0.41° in <0001> (c-axis) direction. The value obtained by dividing the tilt angle distribution in <11-20> (a-axis) direction by the tilt angle distribution in <0001> (c-axis) direction was 1.97. The tilt angle distributions in the two axial directions were substantially constant within the principal plane.

(Substrate Production Example 8)

Following the same procedure as in Substrate Production Example 1, free-standing GaN substrates were arranged as seeds on a susceptor, and were placed in a reactor. Growth was carried out for 45 minutes at a reaction chamber temperature of 1080° C., after which the temperature was lowered to 1020° C. over a period of 30 minutes and growth was carried out at 1020° C. for 77 hours. The amount of fall in temperature during growth was 60° C. The GaN crystal thus obtained was sliced by cutting with a wire, shaped by dicing, then polished using a diamond abrasive and surface polished by CMP, thereby producing a 400 μm thick, square-shaped free-standing GaN substrate which measured 55 mm on a side and whose principal plane was (10-10) plane (M plane). The tilt angle distributions in <11-20> (a-axis) direction and <0001> (c-axis) direction within the plane of the substrate were measured by running x-ray diffraction ω scans at three points in each direction. Of the three measurement points, one point was located at the center of the substrate and two points were located 20 mm away from the center of the substrate. The measurement results, based on 40 mm intervals, were ±4.60° in <11-20> (a-axis) direction and ±1.75° in <0001> (c-axis) direction. The value obtained by dividing the tilt angle distribution in <11-20> (a-axis) direction by the tilt angle distribution in <0001> (c-axis) direction was 2.63. The tilt angle distributions in the two axial directions were substantially constant within the principal plane.

(2) Production of Semiconductor Light-Emitting Device Structure

(Device Structure Fabrication Example 1)

An InGaN-based LED structure targeted at 405 nm emission was fabricated by a MOCVD process on the substrate which was produced in Substrate Production Example 1 and whose principal plane was (10-10) plane. Specifically, the LED structure was fabricated by growing an InGaN/GaN quantum well-containing structure on the substrate. The LED structure was examined under an optical microscope at magnifications of from 50× to 1000×, from which it was confirmed to have been fabricated so as to be flat. The fabricated LED was subjected to photoluminescence (PL) measurement which was carried out at room temperature using a He—Cd laser having a center wavelength of 325 nm as the excitation light source, whereupon light emission from quantum wells near a light-emission wavelength of 405 nm was observed from the entire surface of the wafer.

(Device Structure Fabrication Example 2)

Aside from using the substrate which was produced in Substrate Production Example 2 and whose principal plane was (20-21) plane, an LED structure was fabricated in the same way as in Device Structure Fabrication Example 1. The LED structure was examined under an optical microscope at magnifications of from 50× to 1000×, from which it was confirmed to have been fabricated so as to flat. The fabricated LED was subjected to PL measurement which was carried out at room temperature using a He—Cd laser having a center wavelength of 325 nm as the excitation light source, whereupon light emission from quantum wells near a light-emission wavelength of 405 nm was observed from the entire surface of the wafer.

(Device Structure Fabrication Example 3)

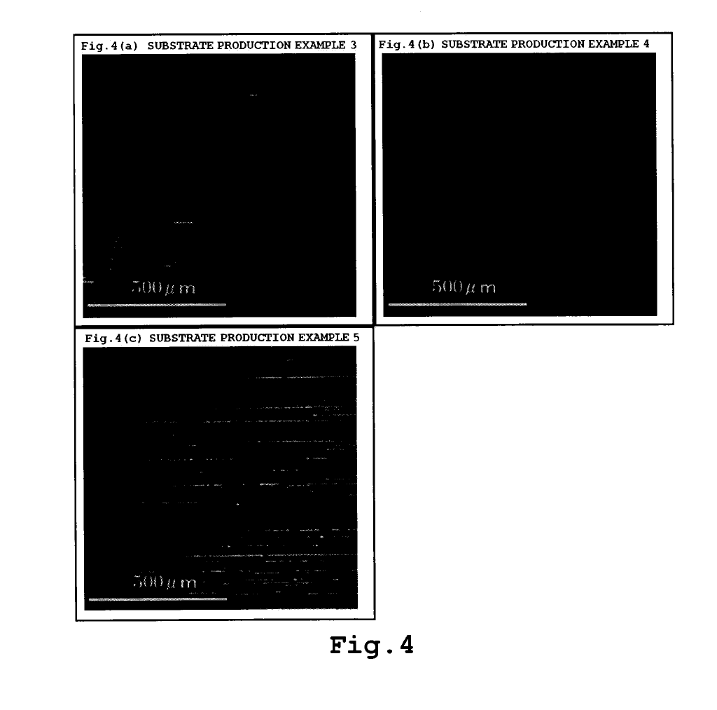

Aside from using the second substrate from the seed side which was produced in Substrate Production Example 3 and whose principal plane was (10-1-1) plane, an LED structure was fabricated in the same way as in Device Structure Fabrication Example 1. The LED fabricated was subjected to PL measurement which was carried out at room temperature using a He—Cd laser having a center wavelength of 325 nm as the excitation light source, whereupon light emission from quantum wells near a light-emission wavelength of 405 nm was observed from the entire surface of the wafer. The PL intensity was 2.147. The surface was examined under a fluorescence microscope at a magnification of 200×, yielding the results shown in FIG. 4(a). In the fluorescence micrograph, the vertical direction is the c-axis direction and the horizontal direction is the a-axis direction. The emission line density was 0 in the low region, and 100 cm⁻¹ in the high region. The emission line corresponds to the long wavelength light emission region.

(Device Structure Fabrication Example 4)

Aside from using the substrate which was produced in Substrate Production Example 4 and whose principal plane was (20-2-1) plane, an LED structure was fabricated in the same way as in Device Structure Fabrication Example 1. The LED fabricated was subjected to PL measurement which was carried out at room temperature using a He—Cd laser having a center wavelength of 325 nm as the excitation light source, whereupon light emission from quantum wells near a light-emission wavelength of 405 nm was observed from the entire surface of the wafer. The PL intensity was 1.707. The surface was examined under a fluorescence microscope at a magnification of 200×, yielding the results shown in FIG. 4(b). In the fluorescence micrograph, the vertical direction is the c-axis direction and the horizontal direction is the a-axis direction. The emission line density was 0 in the low region, and 90 cm⁻¹ in the high region.

(Device Structure Fabrication Example 5)

Aside from using the substrate which was produced in Substrate Production Example 7 and whose principal plane was the (10-10) plane, an LED structure was fabricated in the same way as in Device Structure Fabrication Example 1. The surface of the LED structure was examined under an optical microscope at a magnification of 50×, whereupon the surface was confirmed to be very rough. The LED fabricated was subjected to PL measurement which was carried out at room temperature using a He—Cd laser having a center wavelength of 325 nm as the excitation light source, whereupon no light emission whatsoever was observed from quantum wells near a light-emission wavelength of 405 nm over the entire surface of the wafer; only light emission on the long wavelength side of 440 nm was observed.

(Device Structure Fabrication Example 6)

Aside from using the substrate which was produced in Substrate Production Example 5 and whose principal plane was (10-10) plane, an LED structure was fabricated in the same way as in Device Structure Fabrication Example 1. The LED fabricated was subjected to PL measurement which was carried out at room temperature using a He—Cd laser having a center wavelength of 325 nm as the excitation light source, whereupon the PL intensity was 0.337. The surface was examined under a fluorescence microscope at a magnification of 200×, yielding the results shown in FIG. 4(c). In the fluorescence micrograph, the vertical direction is the c-axis direction and the horizontal direction is the a-axis direction. The emission line density was 0 in the low region, and 500 cm⁻¹ in the high region. Numerous emission lines corresponding to stacking faults were observed in the a-axis direction.

(Discussion)

In each of the semiconductor light-emitting device structures fabricated using the substrates obtained in Substrate Production Examples 1 to 4, which were Group III nitride semiconductor substrates according to the first aspect of the invention, light emission from quantum wells near a light emission wavelength of 405 nm was observed from the entire surface of the wafer (Device Structure Fabrication Examples 1 to 4). On the other hand, in the semiconductor light-emitting device structure fabricated using the substrate obtained in Substrate Production Example 7, which was a Group III nitride semiconductor that does not satisfy the first aspect of the invention, no light emission whatsoever was observed from quantum wells near 405 nm; only light emission on the long wavelength side from 440 nm was observed (Device Structure Fabrication Example 5).

Also, in the semiconductor light-emitting device structures fabricated using the substrates obtained in Substrate Production Examples 1 and 2, which were Group III nitride semiconductor substrates according to the first aspect of the invention, the chip surface was flat (Device Structure Fabrication Examples 1 and 2). On the other hand, the semiconductor light-emitting device structure fabricated using the substrate obtained in Substrate Production Example 7, which was a Group III nitride semiconductor that does not satisfy the W1/W2 ratio serving as a distinctive feature of the first aspect of the invention, had a very rough surface

(Device Structure Fabrication Example 5).

TABLE 1

| | | | | | | | Device Structure | |
|---|---|---|---|---|---|---|---|---|
| | Underlying Substrate | | Free-Standing Substrate | | | | | Light- |
| | Principal | | Principal | | | | | emitting |
| | plane | Off angle | plane | W1 | W2 | W1/W2 | Surface | wavelength |
| Substrate | Semi-polar | 1° in | Non-polar | ±0.11° | ±0.35° | 0.31 | Flat | 405 nm |
| Production | plane | c-axis | plane | | | | | |
| Example 1 | (20-21) | direction | (10-10) | | | | | |
| Device | | | | | | | | |
| Structure | | | | | | | | |
| Fabrication | | | | | | | | |
| Example 1 | | | | | | | | |
| Substrate | Semi-polar | 1° in | Semi-polar | ±0.11° | ±0.33° | 0.33 | Flat | 405 nm |
| Production | plane | c-axis | plane | | | | | |
| Example 2 | (20-21) | direction | (20-21) | | | | | |
| Device | | | | | | | | |
| Structure | | | | | | | | |
| Fabrication | | | | | | | | |
| Example 2 | | | | | | | | |
| Substrate | Semi-polar | none | Non-polar | ±0.21° | ±0.26° | 0.81 | — | 405 nm |
| Production | plane | | plane | | | | | |
| Example 3 | (10-1-1) | | (10-10) | | | | | |
| Device | | | | | | | | |
| Structure | | | | | | | | |
| Fabrication | | | | | | | | |
| Example 3 | | | | | | | | |
| Substrate | Semi-polar | none | Non-polar | ±0.08° | ±0.14° | 0.57 | — | 405 nm |
| Production | plane | | plane | | | | | |
| Example 4 | (20-2-1) | | (10-10) | | | | | |
| Device | | | | | | | | |
| Structure | | | | | | | | |
| Fabrication | | | | | | | | |
| Example 4 | | | | | | | | |
| Substrate | Semi-polar | −1 to 1° | Non-polar | ±0.81° | ±0.41° | 1.97 | Rough | 440 nm |
| Production | plane | in a-axis | plane | | | | | (no light |
| Example 7 | (20-21) | direction | (10-10) | | | | | emission at |
| Device | | | | | | | | 405 nm) |
| Structure | | | | | | | | |
| Fabrication | | | | | | | | |
| Example 5 | | | | | | | | |

The substrates obtained in Substrate Production Examples 3 and 4 and produced by the Group III nitride semiconductor substrate production method serving as the second aspect of the invention were substrates having a high PL intensity and a low emission line density. On the other hand, the substrate that does not satisfy the second aspect of the invention and that was obtained in Substrate Production Example 5 and produced by a Group III nitride semiconductor substrate production method using a non-polar plane as the principal plane of the underlying substrate was a substrate having a low PL intensity and a high emission density.

TABLE 2

| | | | | | | | Device Structure | |
|---|---|---|---|---|---|---|---|---|
| | Underlying | | | | | | | Emission |
| | Substrate | | Free-Standing Plane | | | | | line |
| | Principal | Off | Principal | | | | PL intensity | density |
| | plane | angle | plane | W1 | W2 | W1/W2 | (room temperature) | (cm⁻¹) |
| Substrate | Semi-polar | none | Non-polar | ±0.21° | ±0.26° | 0.81 | 2.147 | 0-100 |
| Production | plane | | plane | | | | | |
| Example 3 | (10-1-1) | | (10-10) | | | | | |
| Substrate | Semi-polar | none | Non-polar | ±0.08° | ±0.14° | 0.57 | 1.707 | 0-90 |
| Production | plane | | plane | | | | | |
| Example 4 | (20-2-1) | | (10-10) | | | | | |
| Substrate | Non-polar | none | Non-polar | ±0.15° | ±0.60° | 0.25 | 0.337 | 0-500 |
| Production | plane | | plane | | | | | |
| Example 5 | (10-10) | | (10-10) | | | | | |

As is apparent from Table 2, in Group III nitride semiconductor substrates of the invention, warpage of the substrate in the direction of the line of intersection between a polar plane and the principal plane is smaller than warpage of the substrate in a direction orthogonal to this line of intersection. Moreover, warpage of the substrate in a direction orthogonal to the line of the intersection is less than 1° per 40 mm, and thus is significantly smaller than in the substrate obtained in Substrate Production Example 5. Also, LEDs fabricated using Group III nitride semiconductor substrates of the invention have a large PL intensity (room temperature). Furthermore, as is apparent also from FIG. 4, emission lines were noted in the direction of the line of intersection between the polar plane and the principal plane, and the generation of stacking faults parallel to the polar plane was confirmed, although the frequency was significantly lower than in Substrate Production Example 5.

In addition, as is apparent from FIGS. 5 and 6, the substrate obtained in Substrate Production Example 6 had stacking fault-associated PL intensities (low temperature) near 3.41 eV which, relative to the band-edge PL intensity, were less than 1 at each point within the principal plane, indicating that the substrate had very few stacking faults. On the other hand, as is apparent from Device Structure Fabrication Example 6, the substrate obtained in Substrate Production Example 5 was a substrate in which numerous stacking faults were present, and the PL intensity (low temperature) at each point on the plane appeared to be more than 1.

### INDUSTRIAL APPLICABILITY

Using the Group III nitride semiconductor substrate of the invention, it is possible to grow a high-quality Group III nitride crystal thereon. Also, LEDs and other semiconductor light-emitting devices having a high light-emitting efficiency can easily be produced by using a Group III nitride crystal grown in this way. Accordingly, the present invention can be advantageously used in the development and production of industrial products which utilize Group III nitride semiconductors, and thus has a high industrial applicability.

The invention has been described in detail and with reference to specific embodiments thereof, it will be apparent to one skilled in the art that various changes and modifications can be made therein without departing from the spirit and scope thereof.

### EXPLANATION OF REFERENCE NUMERALS

1 Group III nitride semiconductor substrate
100 Reactor
101 Carrier gas line
102 Dopant gas line
103 Group III source line
104 Nitrogen source line
105 HCl gas line
106 Group III starting material reservoir
107 Heaters
108 Susceptor
109 Exhaust line
110 Seed
G1 Carrier gas
G2 Dopant gas
G3 Group III source gas
G4 Nitrogen source gas
G5 HCl gas

1. A Group III nitride semiconductor substrate having a plane other than a C plane as a principal plane,
wherein a ratio (W1/W2) of a tilt angle distribution W1 of the principal plane in the direction of a line of intersection between the principal plane and the C plane to a tilt angle distribution W2 of the principal plane in a direction orthogonal to the line of intersection is less than 1.

2. The Group III nitride semiconductor substrate according to claim 1, which is a Group III nitride semiconductor substrate having, as the principal plane, an M plane or a plane tilted less than 90° in a c-axis direction from the M plane.

3. The Group III nitride semiconductor substrate according to claim 1, wherein the tilt angle distribution W1 is less than ±1° per 40 mm interval.

4. The Group III nitride semiconductor substrate according to claim 1, wherein the tilt angle distribution W2 is ±0.01° or more and less than ±1° per 40 mm interval.

5. A method for producing a Group III nitride semiconductor crystal, the method comprising growing a Group III nitride semiconductor crystal on the Group III nitride semiconductor substrate according to claim 1.

6. A method for producing a semiconductor light-emitting device, the method comprising the step of growing a Group III nitride semiconductor crystal on the Group III nitride semiconductor substrate according to claim 1.

7. A semiconductor light-emitting device produced by the method according to claim 6.

8. The semiconductor light-emitting device according to claim 7, wherein the device is an LED.

9. A method for producing a Group III nitride semiconductor substrate, the method comprising:
(1) a first step of obtaining a Group III nitride semiconductor crystal by carrying out homoepitaxial growth on a semi-polar plane of a Group III nitride seed having the semi-polar plane as a principal plane; and
(2) a second step of acquiring, from the Group III nitride semiconductor crystal, a Group III nitride semiconductor substrate having a plane differing from the semi-polar plane as a principal plane.

10. The Group III nitride semiconductor substrate production method according to claim 9, wherein the Group III nitride seed comprises a plurality of Group III nitride seeds, and the Group III nitride seeds are arranged on a same flat surface in such a way that a distribution of plane directions between the principal planes of the seeds is within ±0.5°.

11. The Group III nitride semiconductor substrate production method according to claim 9, wherein the Group III nitride seeds are arranged so as to satisfy a condition of the following formula:
Sa/Sc≧1
(In the formula, Sa is a sum of contact distances between edges in the direction of lines of intersection between polar planes and principal planes of the Group III nitride seeds, and Sc is a sum of contact distances between other edges.).

12. The Group III nitride semiconductor substrate production method according to claim 9, wherein the Group III nitride seeds has feature that a total surface area of (0001) planes of the seeds is smaller than a total surface area of (000-1) planes.

13. The Group III nitride semiconductor substrate production method according to claim 9, wherein, in the first step, crystal growth is carried out while controlling an amount of fall in temperature during crystal growth so as to be within 60° C.
